(19) United States
(12) Patent Application Publication
(10) Pub. No.: US 2011/0136324 A1
(43) Pub. Date: Jun. 9, 2011

(54) SEMICONDUCTOR DICE TRANSFER-ENABLING APPARATUS AND METHOD FOR MANUFACTURING TRANSFER-ENABLING APPARATUS

(75) Inventors: Ian Ashdown, West Vancouver (CA); Ingo Speier, Saanichton (CA); Calvin Wade Sheen, Derry, NH (US)

(73) Assignee: COOLEDGE LIGHTING, INC., Vancouver (CA)

(21) Appl. No.: 12/963,609

(22) Filed: Dec. 8, 2010

Related U.S. Application Data
(60) Provisional application No. 61/285,134, filed on Dec. 9, 2009.
(60) Provisional application No. 61/287,797, filed on Dec. 18, 2009.
(60) Provisional application No. 61/375,127, filed on Aug. 19, 2010.

(51) Int. Cl. H01L 21/78; B26F 3/00

(52) U.S. Cl. 438/464; 225/93; 257/E21.599

(57) ABSTRACT

A transfer-enabling apparatus, produced by a method of manufacturing, includes a substrate patterned with islands separated by trenches and an epitaxial layer, grown at least on the islands, providing semiconductor dice in such a configuration partially released from said substrate and suspended over the substrate, and interconnected, by anchors of epitaxial or other material that are attached to the substrate. The anchors are of width less than or equal to than the semiconductor dice and define fracture zones at connections of the anchors with the semiconductor dice.

This patent application claims the benefit of U.S. provisional application Nos. 61/285,134, 61/287,797 and 61/375,127, respectively filed Dec. 9, 2009, Dec. 18, 2009 and Aug. 19, 2010. The disclosures of said provisional applications are hereby incorporated herein by reference thereto.

### TECHNICAL FIELD

The subject matter of the present invention is directed generally to the manufacture of transferable semiconductor dice and, more particularly, is concerned with a transfer-enabling apparatus providing semiconductor dice on a first substrate with anchors such that the dice can be transferred from the first substrate to a second substrate, and a method for manufacturing the transfer-enabling apparatus.

### BACKGROUND ART

Illumination based on semiconductor light sources such as light-emitting diodes (LEDs) offers an efficient and long-lived alternative to fluorescent, high-intensity discharge, and incandescent lamps. Many LED light sources employ high-powered LEDs, which pose thermal management and other related problems. Another drawback with state-of-the-art LED devices is their high initial cost.

Currently, gallium nitride (GaN)-based LEDs are epitaxially grown on sapphire wafers, following which the wafers are scribed with a laser or diamond stylus and then mechanically cleaved into individual LED dice. This process limits the minimum size of the dice that can be economically generated from the wafers, as there needs to be a minimum spacing for the “streets” between the dice. At some point the area occupied by the streets exceeds the economic yield of small dice from the wafer.

Small semiconductor dice, including sizes of 300 μm or smaller, provide many benefits in applications such as broad area lighting, concentrator photovoltaics and electronics. However, dice of this scale cannot be economically generated from a source wafer using conventional wafer dicing techniques.

It is also difficult to transfer small LED dice to a target substrate using conventional “pick-and-place” robotic handling systems, as the various electrostatic and van der Waal forces tend to cause the dice to adhere to the pickup tools. Further, the small size of the dice exacerbates the need to maintain precise positioning and orientation in order to successfully connect the dice electrodes with electrical connectors on the target substrate.

There is therefore a need for an innovation whereby small semiconductor dice can be economically generated from a source wafer and transferred to a target substrate while maintaining precise positioning and orientation.

### SUMMARY OF THE INVENTION

The subject matter of the present invention provides such an innovation wherein growth of high quality and high performance GaN-based LEDs on a source substrate is achieved, while at the same time a transfer-enabling apparatus for easy and cost-effective transfer of the LED dice from the wafer to a target substrate and a method for manufacturing the transfer-enabling apparatus are provided.

One aspect of the present invention is a method for manufacturing a transfer-enabling apparatus which includes patterning a source substrate, growing epitaxial layers on the patterned substrate, creating epitaxial islands that include semiconductor dice interconnected by anchors of width less than or equal to the dice, and partially releasing the semiconductor dice from the substrate to form the transfer-enabling apparatus wherein the semiconductor dice remain interconnected one to the next and suspended above the source substrate by the anchors.

Another aspect of the present invention is a transfer-enabling apparatus, produced by the manufacturing method, which includes a source substrate patterned with islands separated by trenches and an epitaxial layer, grown at least on the islands, providing semiconductor dice partially released from the substrate and suspended over the substrate, and interconnected, by anchors of epitaxial or other material that are attached to the substrate. The anchors are of width less than or equal to the semiconductor dice and define fracture zones at connections of the anchors with the semiconductor dice.

More particularly, the source substrate allows for growth of the desired epitaxial layer or layers and also allows an optional first sacrificial layer to be epitaxially grown on the source substrate. The source substrate or sacrificial layer is patterned with trenches to create a single-level or dual-level (upper and lower level) surface profile. One or more epitaxial layers are grown on the patterned substrate, thereby creating islands of semiconductor dice. The epitaxial material is then released from the source substrate, a portion of the source substrate, or a sacrificial layer of the substrate, using wet etching, dry etching, or laser liftoff techniques, creating suspended semiconductor dice interconnected with the anchors that enable transfer to a target substrate using transfer stamp printing or wafer bonding techniques.

The method reduces manufacturing complexity and cost, and at the same time increases epitaxial quality and yield. A particular advantage of the anchors is that they maintain the position and orientation of the semiconductor dice during transfer by the apparatus with subnanometer precision, thereby enabling a variety of transfer techniques that would not otherwise be possible.

The shape and depth of the trenches and the thickness of the epitaxial growth material are chosen to leave parts of the side walls of the substrate exposed, thus allowing the die release process to proceed from these surfaces. The shape and depth of the trenches and the thickness of the epitaxial growth material and any other additional material are also chosen to provide temporary anchoring of the semiconductor during the release process and to provide for easy semiconductor die transfer from the source substrate.

### BRIEF DESCRIPTION OF THE DRAWINGS

For clarity, the drawings herein are not necessarily to scale, and have been provided as such in order to illustrate the principles of the subject matter, not to limit the invention.

FIG. 1 is a flow diagram of a sequence of basic steps of a method of manufacturing a transfer-enabling apparatus in accordance with the present invention.

FIG. 2A is a plan schematic view of an unpatterned substrate.

FIG. 2B is a plan schematic view of the substrate of FIG. 2A after patterning single-level trenches.

FIG. 2C is an enlarged perspective schematic view of a portion of the patterned substrate of FIG. 2B with the single-level trenches.

FIG. 2D is an enlarged plan schematic view of a portion of the patterned substrate of FIG. 2B that is further etched to provide two-level trenches.

FIG. 2E is an enlarged perspective schematic view of a portion of the patterned substrate of FIG. 2D with the two-level trenches.

FIG. 3A is a sectional schematic view seen along section line AA-AA in FIG. 2D where the patterned substrate is a trenched silicon substrate with an epitaxial layer.

FIG. 3B is a sectional schematic view seen along section line BB-BB in FIG. 2D where the patterned substrate is a partially released epitaxial layer on a silicon substrate.

FIG. 3C is a sectional schematic view seen along section line AA-AA in FIG. 2D where the patterned substrate is a trenched sapphire substrate without an epitaxial layer.

FIG. 3D is a sectional schematic view seen along section line AA-AA in FIG. 2D where the patterned substrate is a trenched sapphire substrate with an epitaxial layer.

FIG. 3E is a sectional schematic view seen along section line BB-BB in FIG. 2D where the patterned substrate is a partially released epitaxial layer on a sapphire substrate.

FIGS. 4A-4E are plan schematic view of various exemplary embodiments of transfer-enabled apparatus each having semiconductor dice and temporary anchors in accordance with the present invention.

FIGS. 5A and 5B are side schematic view of two embodiments of a substrate after a first etching step.

FIG. 6 is a side schematic view of an embodiment of a composite substrate.

FIG. 7A is a side schematic view of an embodiment of another composite substrate.

FIG. 7B is a sectional schematic view of the composite substrate of FIG. 7A with trenches formed after two etching steps.

FIGS. 8A-8E are schematic view of stages of the apparatus in the steps of the manufacturing method using non-epitaxial anchors.

FIGS. 9A-9D are schematic view of stages of the apparatus in the steps of the manufacturing method providing non-epitaxial anchors using a buried oxide layer.

### DETAILED DESCRIPTION OF THE INVENTION

The term semiconductor die (plural dice) includes light-emitting elements, which is any device that emits electromagnetic radiation within a wavelength regime of interest, for example, visible, infrared or ultraviolet regime, when activated, by applying a potential difference across the device or passing a current through the device. Examples of light-emitting elements include solid-state, organic, polymer, phosphor coated or high-flux light-emitting diodes (LEDs), micro-LEDs, laser diodes or other similar devices as would be readily understood. Without limiting the foregoing, micro-LEDs include LEDs comprised of one or more semiconductor die with lateral dimensions 300 μm or smaller. The output radiation of an LED may be visible, such as red, blue or green, or invisible, such as infrared or ultraviolet. An LED may produce radiation of a spread of wavelengths. An LED may comprise a phosphor for converting part of its output from one wavelength to another. An LED may comprise multiple semiconductor dice, each emitting substantially the same or different wavelengths.

While LEDs have been used as examples of transferable elements that can be made by the method of the present invention, other semiconductor dice can equally be made, for example, integrated circuits, photovoltaic cells (for example single junction or multi-junction cells for concentrator photovoltaic applications), transistors, photodiodes, laser diodes, resistors, capacitors, and non-emitting diodes. Semiconductor dice made by the disclosed method may be used in electronic devices or in modules that can be incorporated in electronic devices. For example, a luminaire may comprise elements made by the method of the disclosed subject matter.

Basics of Manufacturing Method and Transfer-Enabling Apparatus

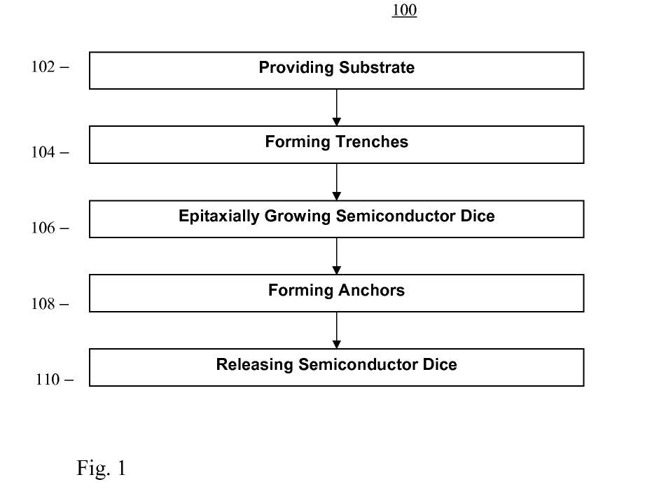

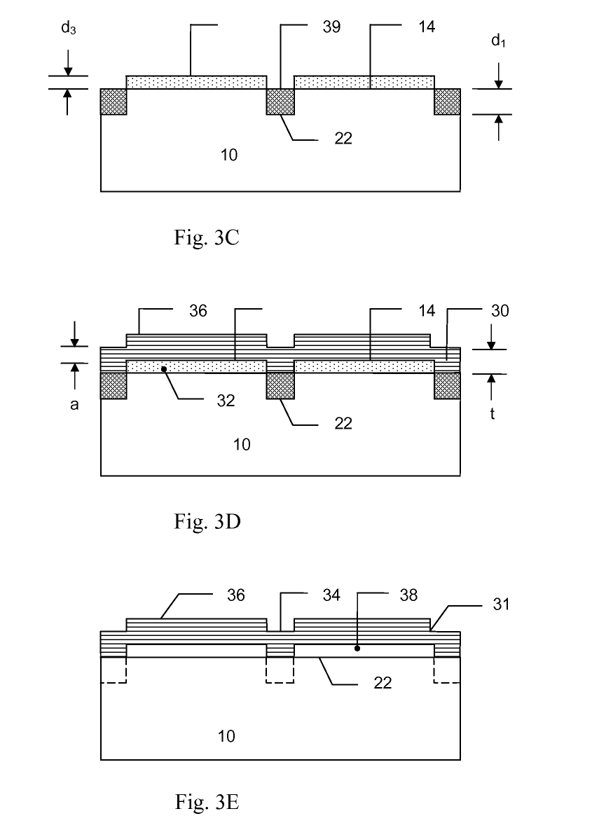

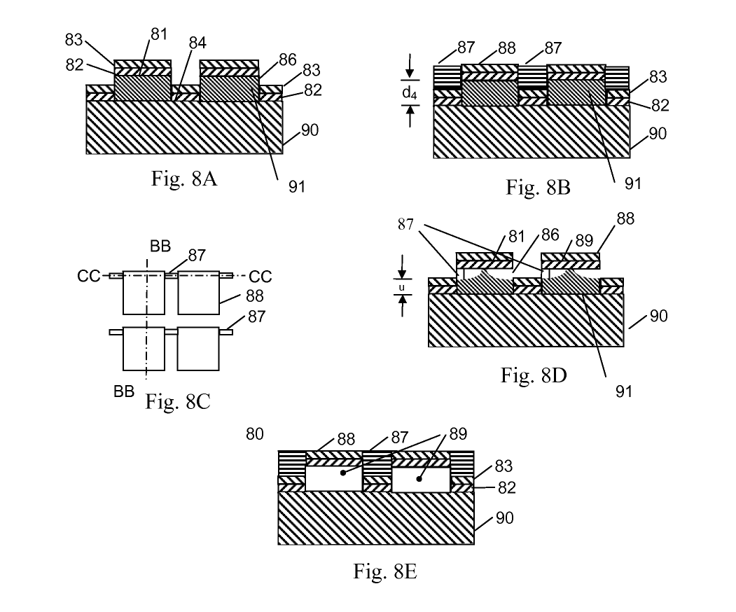

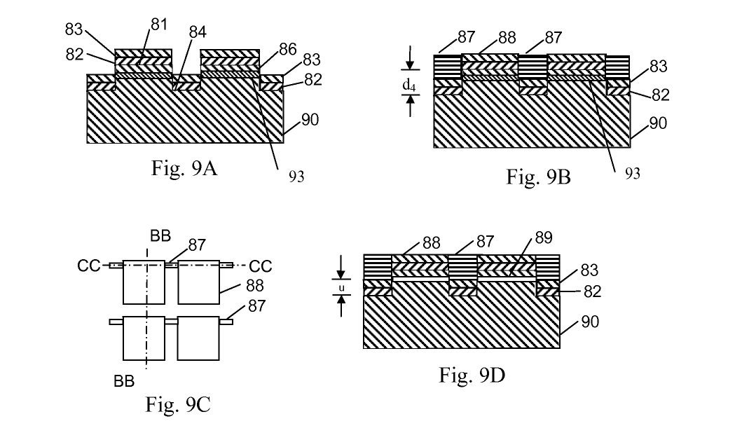

Referring now to FIG. 1, there is shown a flow diagram 100 of the basic steps of a method of manufacturing in accordance with the present invention to produce exemplary embodiments of a transfer-enabling apparatus 4, as shown in FIG. 3B, or 80, as shown in FIG. 8E, also in accordance with the present invention. For sake of simplicity, the following description of the manufacturing method with reference to flow diagram 100 will be limited to manufacture of the transfer-enabling apparatus 4. Except for a brief introductory discussion of the two categories of anchors presented below in the description of step 108 of the flow diagram 100, description of the manufacture of transfer-enabling apparatus 80 will be presented later below with reference to FIGS. 8A-8E and 9A-9D.

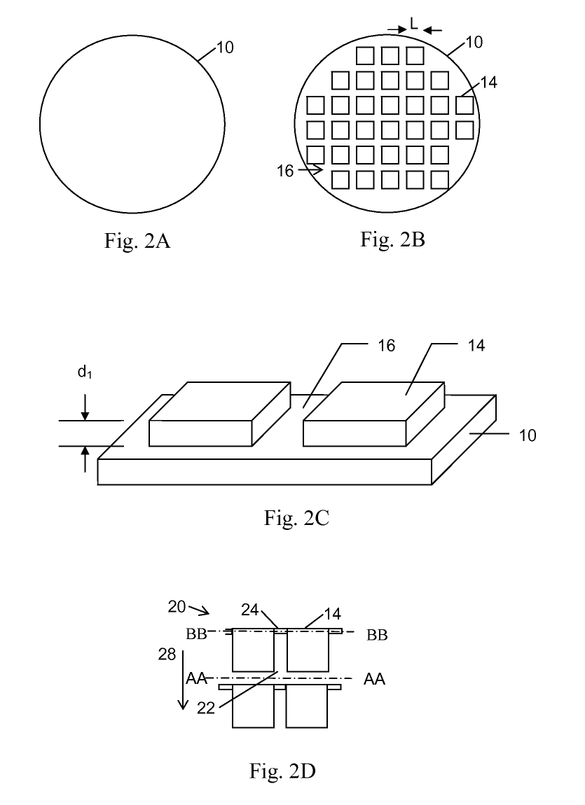

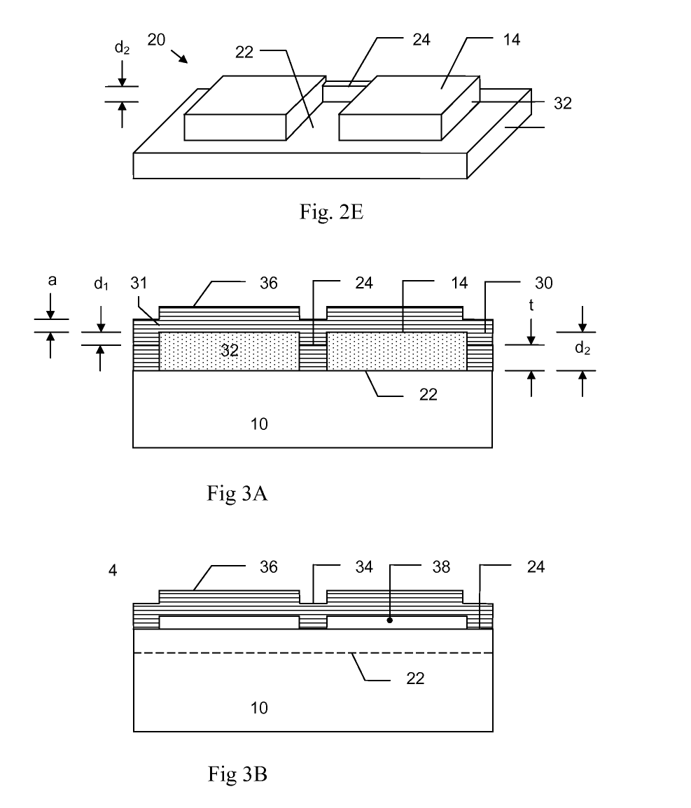

In step 102 of the flow diagram 100 of FIG. 1, a source substrate 10 is provided as shown in FIG. 2A. The material of substrate 10, for example, can be a silicon (111) substrate, a sapphire substrate, or other substrate as will be mentioned below. Also, as will be described below in more detail, the source substrate 10 has an upper layer that constitutes a sacrificial layer. The substrate 10 is chosen such that single-level as shown in FIG. 2C, dual-level as shown in FIG. 2E, or multi-level surface profiles can be patterned into the substrate material.

In step 104 of the flow diagram 100 of FIG. 1, trenches 16 and 22 shown in FIGS. 2B and 2D are patterned in the substrate 10 so as to create islands 14 thereon. A particular patterning technique is selected such that the trenches 16 will be single-level (have essentially the same depth) as shown in FIGS. 2B and 2C, or the trenches 16, 22 will be dual, or upper and lower, levels (have two different depths) as shown in FIGS. 2D and 2E. The particular patterning techniques selected will depend on the type of anchors, epitaxial and non-epitaxial (to be described below), to be produced as part of the transfer-enabling apparatus. Also, as can be seen in FIGS. 2D and 2E, the upper level has a width less than or equal to the lower level. Patterning of the trenches 16 and 22 can be performed by several known methods, including wet etching, reactive ion etching, ECR (electron cyclotron resonance) etching, ICP (inductively coupled plasma) etching or other dry etching process, laser-induced ablation, or mechanical cutting. The depth of each etching step may be controlled by incorporating etch stops (see below) into the substrate, by controlling the time of the etching process, or any other means known to those skilled in the art.

In step 106 of the flow diagram 100 of FIG. 1, an epitaxial layer 30, as shown in FIG. 3A, is grown on the patterned substrate 10 such that semiconductor dice 36 are formed on the islands 14. The epitaxial layer 30 is grown such that certain faces of the substrate 10 remain accessible, from which release etching or laser liftoff can proceed as described below.

In step 108 of the flow diagram 100 of FIG. 1, anchors 34 or 87, as seen in FIG. 3B or 8E are formed between and interconnect the semiconductor dice 36 or 88 in the trenches 16, 22 and 84 (FIG. 8A) of the substrate 10 or 90. The anchors are provided to interconnect and secure the semiconductor dice one to the next and also individually to the substrate 10 or 90 during and after the release step 110 to be described below. The anchors 34 or 87 are of a width less than or equal to the width of the semiconductor dice 36 or 88. Anchors are grouped in two different categories. Depending on the type of anchor desired, forming of the anchors 34 as shown in FIG. 3B may begin in step 108 concurrently with the growth of the epitaxial layer 30 in step 106 (epitaxial anchor) as shown in FIG. 3A, or may be (non-epitaxial) deposited in step 108 occurring after epitaxial growth in step 106. The construction of these categories of anchors will be described in detail below. Briefly regarding the first category, epitaxial anchors 34 (FIG. 3B), as mentioned above, are created during the growth of the epitaxial layer 30. The surface profile of the substrate 10 is created such that during the growth of the epitaxial layer (or layers) 30 an overlap of the epitaxial material deposited in specific locations in the trenches 16 and 22 overlaps with epitaxial material grown on the islands 14, creating a connection. Briefly regarding the second category, non-epitaxial anchors 87 (FIG. 8E) can be fabricated of metallic, photoresist or other organic materials and are created after completion of the epitaxial growth in step 106. The position and shape of the anchors 87 can be defined through a photolithographic metallization process or a localized deposition including droplet dispensing, inkjet deposition, or screen printing. Materials include but are not limited to metals and polymers such as photoresist or epoxy.

In step 110 of the flow diagram of FIG. 1, after previous growth of the epitaxial layer 30 and formation of the anchor structure 34, the semiconductor dice 36 are partially released from the substrate 10 by removal of the sacrificial layer (SiO₂ or exposed Si layer for example), resulting in the transfer-enabling apparatus 4 in accordance with the present invention having one or more semiconductor dice 36 that are suspended above the source substrate 10 by the anchors 34. The transfer-enabling apparatus 4 so produced includes the substrate 10 patterned with islands 14 separated by trenches 16, 22 and an epitaxial layer 30, grown at least on the islands 14, providing semiconductor dice 36 partially released from the substrate 10 and suspended over the substrate 10, and interconnected, by anchors 34 of epitaxial or other material that are attached to the substrate 10. The anchors 34 are of width less than or equal to the semiconductor dice 36 and define fracture zones 31 at connections of the anchors 34 with the semiconductor dice 36.

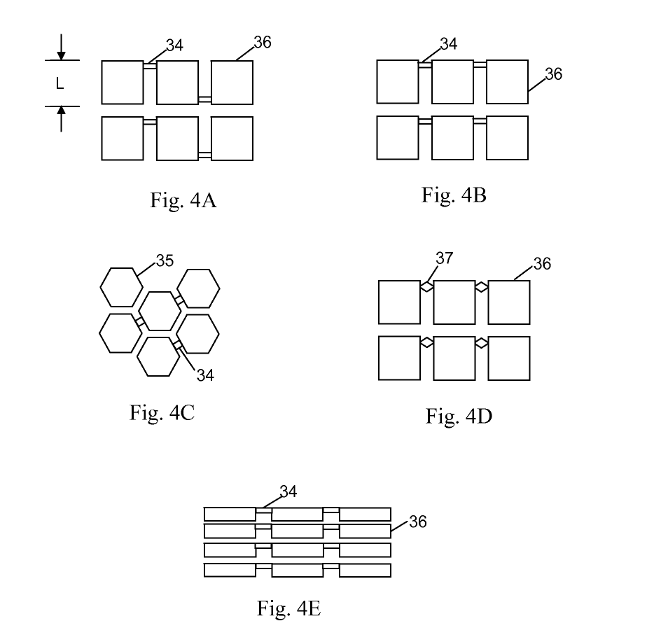

The above-described manufacturing method allows for a wide variety of sizes and shapes of semiconductor dice 36, as shown in FIGS. 4A-4E. FIGS. 4A, 4B and 4D each displays a square semiconductor chip, FIG. 4C a hexagonal design and FIG. 4E a rectangular design. It should be readily understood that also circular, elliptical, triangular, compound shapes or irregular shapes or other shapes known to those skilled in the art can be utilized. The size and shape of the semiconductor dice can be optimized for parameters such as epitaxial usage and die performance. In one example shown in FIG. 4E, the semiconductor dice are rectangular LEDs each with a large length over width ratio. A large length-over-width ratio can be beneficial in LED performance. Furthermore a rectangular or square design provides high wafer utilization. In a different example, the linear dimension L of a square design could be 100 μm, in another example L could be any value included the range 25 μm to 200 μm, and in yet another example, the dimension L could be a value outside this range.

Also FIGS. 4A-4E illustrate that many different shapes and positions of either of the two categories of anchors are possible. Regarding the epitaxial anchors, in FIG. 4A the anchors 34 are shown at or near diagonally opposite corners of the semiconductor dice 36. In FIGS. 4B and 4E, the anchors 34 are at or near adjacent corners of the semiconductor dice 36. In FIG. 4C, the semiconductor dice 35 are hexagonal and are joined with anchors 34 at the mid-point of a side of a semiconductor die. In FIG. 4D, the anchors 37 are approximately diamond shaped and hold the semiconductor dice 36 in place at two adjacent corners of each semiconductor die. These are just a few examples of the many possibilities of anchors. Further, there may be one or more anchors per chip. The design of the anchors can be optimized for high transfer yield, for minimum defect propagation within the semiconductor dice when the anchors break, or for minimum damage to the semiconductor dice.

As briefly mentioned above, the materials of substrate include but are not limited to silicon, specifically crystalline Si on the Si(111) plane, SiO₂ on silicon, silicon on oxide materials (SOI) with one or more buried oxide layers, and sapphire. In one embodiment the substrate may contain one or more etch stop layers that allow for consistent etch depth when defining the surface pattern.

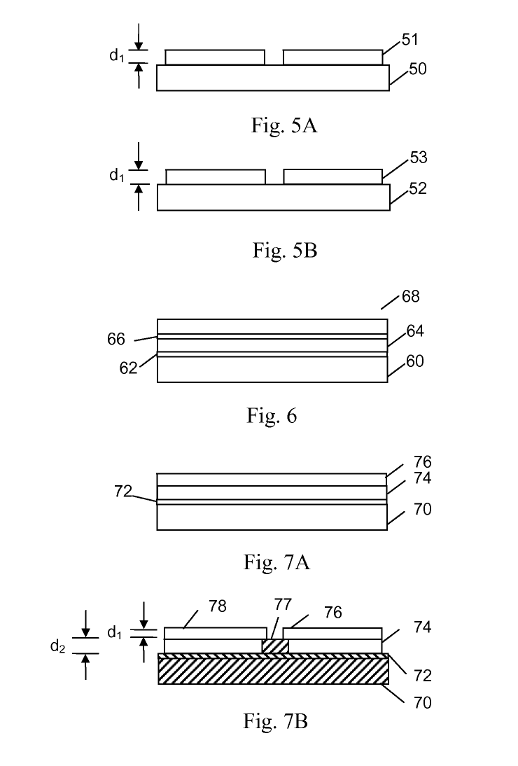

For example, in FIG. 5A the substrate has a SiO₂ layer 51 on top of a silicon layer 50. In the first etching step, the top layer 51 is etched through to the lower silicon layer 50, which acts as an etch stop.

In FIG. 5B, the substrate has a sacrificial GaN layer 53 on top of a patterned sapphire layer 52. In the first etching step, the top layer 53 is etched through to the lower sapphire layer 52, which acts as an etch stop.

FIG. 6 shows another example of a substrate suitable for a two-level etching process, which contains a lower silicon layer 60, a first etch stop layer 62, a middle silicon layer 64, a second etch stop layer 66, and an upper silicon layer 68.

In a different example displayed in FIG. 7A, the substrate has a silicon layer 70, an etch stop layer 72, a second silicon layer 74, and a SiO₂ layer 76. During the first etching step, the trenches are etched down a first depth d₁ as shown in FIG. 7B, resulting in upper portions 77 of the trenches and substrate islands 78. In a second etching step, parts of the trenches are further etched down a distance d₂ to the etch stop layer 72. In the subsequent epitaxial growth step, the epitaxial layer forms anchors over upper regions 77 of the trenches.

In general, the substrate may contain one or more etch stop layers that allow for effective patterning of the substrate. The substrate also may contain buffer layers needed for example to grow LED epitaxial wafers such as GaN on Si or sapphire, or to grow AlInGaP on GaAs.

As also briefly mentioned above, the source substrate 10 includes an upper sacrificial layer. The sacrificial layer will be removed in step 110 in order to release the semiconductor dice 36 from the source substrate 10 (leaving the dice 36 only indirectly connected to the substrate 10 by the anchors 34). In the case of a silicon-based substrate, the sacrificial layer includes but is not limited to SiO₂ or the silicon substrate itself. In the case of a sapphire substrate, the sacrificial layer includes but is not limited to GaN. The following are different embodiments that may be selected for releasing the semiconductor dice 36 from the source substrate 10 (except for the interconnection still provided by the anchor structures).

In a first embodiment, the epitaxial material is grown on Si(111) and the silicon substrate is etched making use of the preferential etching of Si on the Si(111) plane in the Si(110) direction in a potassium hydroxide (KOH) etch.

In a second embodiment, the epitaxial layer is grown directly on SiO₂ or on SOI and the sacrificial oxide layer is removed in an isotropic etching process with BOE (buffered oxide etch) or hydrofluoric acid (HF).

In a third embodiment, a GaAs substrate is used and sacrificial layers include but are not limited to oxide layers, Al-rich AlGaAs layers, and AlAs layers that can be removed by a wet etching process. It is understood that the sacrificial layers and etch chemistries mentioned above are only examples and different sacrificial layers and etch chemistries can be selected.

In a fourth embodiment, the epitaxial material is grown on a patterned sapphire substrate and the sacrificial GaN layer is removed by means of directing a pulse of coherent ultraviolet radiation through the sapphire substrate to decompose the GaN into its constituent gallium and nitrogen components in a process commonly referred to as “laser liftoff.”

Details of Embodiments with Epitaxial and Non-Epitaxial Anchors

In an exemplary embodiment, the manufacturing method depicted by the flow diagram 100, as described initially above, is performed to produce the transfer-enabled apparatus 4, as shown in FIG. 3B, having the first category epitaxial anchors 34. A substrate 10 provided in step 102 is subjected to a first or level-one of a dual-level etching in step 104, using the known techniques mentioned above. This first etching produces trenches 16 between islands 14 of a depth d₁ as shown in FIG. 2C. The shape and size of the islands 14 approximately define the two-dimensional shape and size of the semiconductor dice 36 to be ultimately produced in the epitaxial growth step 106. In the example shown, the substrate island 14 has a linear dimension L of about 100 um and an approximately square form.

Following thereafter, a second or level-two of the dual-level etching is carried out in step 104, again using known techniques, producing the features shown in FIGS. 2D and 2E. In this second etching, the existing or initial trenches 16 are further etched in part to form deeper portions of trench. FIGS. 2D and 2E show a fragment of the initially patterned substrate 10 to illustrate the part that has been further etched so as to produce regions 20 forming second trenches 22. As a result of the second etching, the first and second trenches 16, 22 have two levels. Regions 24 of the initial or first trenches 16 that are not further etched, are less deep than regions 20 of the further etched second trenches 22, resulting in greater exposure of the side faces 32 of the substrate islands 14.

After the two etchings in step 104, the epitaxial layer 30 is grown in step 106 to a thickness t, as shown in FIG. 3A. The epitaxial layer 30 may include one or more layers of the same or different materials. For example the epitaxial layer may be a blue LED and the structure may include a buffer layer, a n-doped layer, one or more active layers (single or multi quantum well), and a p-doped layer. When comparing FIG. 2E to FIGS. 3A and 3B, it can be seen that the epitaxial layer 30 has been grown on both levels (or the bottom surfaces) of the trenches 22, 16 as well as on the surfaces of the substrate islands 14. In effect, relative to the level of the top surfaces of islands 14, the epitaxial growth of layer 30 to thickness t “overgrows” region 24 of first trench 16 but “undergrows” region 20 of second trench 22. The depth d₁ of the region 24 of the first trench 16, the depth d₂, of the region 20 of the second trench 22, and the thickness t of the epitaxial growth layer 30 are chosen such that vertical overlap between portions of the epitaxial growth layer 30 deposited on the island 14 and in the first trench 16 is achieved due to the “overgrowing” of the region 24, while maintaining a gap between the portions of the epitaxial growth layer 30 deposited on the island 14 and in the second trench 22 is achieved due to the “undergrowing” of the region 20.

In step 108, the portion of the epitaxial growth layer 30 deposited on first trench 16 so as to “overgrow” region 24 concurrently forms the epitaxial anchors 34 that attach to the substrate 10 (via first trench 16) and also, due the aforementioned overlap, provide interconnections between the semiconductor dice 36. Referring to FIG. 3A, the thickness t of the epitaxial layer 30 satisfies the following conditions:

t<d₁+d₂

t>d₁

The thickness of the aforementioned vertical overlap is a=t−d₁. In the situation that the epitaxial layer 30 contains an active layer sandwiched between n and p type layers the thickness of the d₁, d₂ and t can be selected such that vertical overlap provides an intersecting fracture zone 31 through the anchors 34 that occurs only below the active layer of the epitaxy (semiconductor dice) 36 deposited on the substrate islands 14.

After epitaxial growth of layer 30 in steps 106 and 108 is carried out, the semiconductor dice 36 formed on the substrate islands 14 may be subject to further processing, such as definition of p and n contacts, metallization, annealing and passivation. After such further processing, if any, in step 110, the substrate 10 is etched via the exposed side faces 32 of the substrate islands 14, which results in the partial release of the semiconductor dice 36 from the substrate 10, as seen in FIG. 3B.

Partial release of the semiconductor dice 36 can be performed using one of several known methods including wet etching processes. The etching process results in the top portions of the substrate islands 14 being etched away via the side face portions 32. For example, the substrate 10 can be etched using potassium hydroxide (KOH). For KOH etch of Si the etching will preferentially occur in Si(110) direction removing the silicon material underneath the semiconductor die 36. If the sacrificial layer is an oxide material, it can be etched with hydrogen fluoride or BOE (buffered oxide etch) resulting in isotropic etch and removal of the oxide material. In FIG. 3B the transfer-enabling apparatus 4 is shown which includes semiconductor die 36 suspended over the remaining substrate 10 with the gap 38 created by release etching the substrate 10 exposed to the etchant via the side surface, and supported by the epitaxial anchors 34 grown in the regions 24 of the first trenches 16. Epitaxial anchors 34 will continue to hold the semiconductor dice 36 in place relative to one another and to the substrate 10 after completion of the release step 110. The semiconductor dice 36 are now only partially released from the silicon or sapphire substrate 10 due to the presence of the epitaxial anchors 34 (FIG. 3B) which interconnect the semiconductor dice 36 to one another and to the substrate 10.

The thickness t of the epitaxial layer 30 and the depth d₁ of the region 24 of the first trench 16 can be selected so that the resulting epitaxial anchors 34 can be easily broken or fractured by a preselected force, such as a vertical force, an oblique force, a shear force, a combination of these forces or a torque, for example if the semiconductor dice 36 are peeled off. The preselected force needed to break the epitaxial anchors 34 can be provided when transferring the grown semiconductor dice 34 using, for example, a stamping or wafer bonding process.

A particular advantage of the present invention is that the thickness a=t−d₁ of the vertical overlap, tailored to produce an intersecting fracture zone 31 between the anchors 34 and the semiconductor dice 36, provides a degree of freedom in the design of the anchors 34 that is not available with the prior art. In particular, the geometry of the anchors 34 can be designed such that they more easily fracture in response to vertical forces while being resistant to horizontal shear forces or torsional forces. In addition, the fracture zone 31 provides a well-defined edge to the semiconductor die 36 when it is separated from anchor 34. This is important in that it for example light losses at the edge of an LED. This minimizes the possibility of the semiconductor dice 36 becoming misaligned on the transfer-enabling apparatus 4 during the transfer process.

In another exemplary embodiment, the manufacturing method depicted by the flow diagram 100, as described initially above, is performed to produce the transfer-enabled apparatus 4, as shown in FIG. 3E, also having the first category epitaxial anchors 34. A sapphire substrate 10 provided in step 102 is patterned by being subjected to a first or level-one etching or the like in step 104, producing the first trench 16 defining the first region 20 between the two substrate islands 14, as shown in FIG. 2C. The trench 16 is of a depth d₁ as shown in FIG. 2C. The patterning may use, for example, dry etching, laser ablation, or mechanical milling techniques.

After the level-one etching in step 104 is carried out, also in step 104 a level-two trenching operation takes place, as seen in FIG. 3C, wherein a first layer 39 of for example GaN with thickness d₁ is epitaxially grown between substrate islands 14 in FIGS. 2E and 3C, and a second sacrificial layer 40 of for example GaN with thickness d₃ is epitaxially grown on substrate islands 14, as shown in FIG. 3C.

In step 106, epitaxial layer 30 with thickness t is then epitaxially grown, as shown in FIG. 3D, on the first and second layers 39, 40. The epitaxial layer 30 may include one or more layers of the same or different materials. For example the epitaxial layer 30 may be a blue LED and the structure may include a buffer layer, a n-doped layer, one or more active layers (single or multi quantum well), and a p-doped layer. The depth d₁ of the first layer 39, the thickness d₃ of the second sacrificial layer 40, and the thickness of the epitaxial layer t, are chosen such that vertical overlap between epitaxial layer 30 deposited on first and second layers 39 and 40 is achieved in the same way as in the previous embodiment described above, while maintaining a gap between the portions of the epitaxial layer 30 deposited on the second layers 40 (on islands 14) and in the region of trench 22 is achieved also in the same way as in the previous embodiment described above.

In step 108, the portion of the epitaxial layer 30 deposited in region 24 will concurrently form the anchors 34 to semiconductor dice 36. The anchors 34 The thickness of the epitaxial layer 30 satisfies the following conditions:

t<d₁+d₃

t>d₁

The thickness of the aforementioned vertical overlap is a=t−d₁. In the situation that the epitaxial layer 30 contains an active layer sandwiched between n and p type layers the thickness of the d₁, d₂ and t can be selected such that vertical overlap occurs only below the active layer of the epitaxy (semiconductor dice) 36 deposited on the substrate islands 14.

After the epitaxial growth in step 106 is carried out, the semiconductor dice 36 being formed on the substrate islands 14 may be subject to further processing, such as definition of p and n contacts, metallization, annealing and passivation. After such further processing, if any, in step 110, the substrate 10 is etched via the exposed side faces 32 of the substrate islands 14, which results in the partial release of the semiconductor dice 36 from the substrate 10, as seen in FIG. 3E.

Partial release of the semiconductor dice in step 110 can be performed using a laser liftoff process. The liftoff process results in the sacrificial layer 40 being ablated with the resultant plasma being vented via the side portions 32. In FIG. 3E the transfer-enabling apparatus 4 is shown which includes semiconductor die 36 suspended over the remaining substrate 10 with the gap 38 created by laser ablation of the sacrificial GaN layer 40, and supported by the epitaxial anchors 34 grown on the layer 39. Epitaxial anchors 34 will continue to hold the semiconductor dice 36 in place relative to one another and to the substrate 10 after completion of the release step 110. The semiconductor dice 36 are now only partially released from the sapphire substrate 10 due to the presence of the epitaxial anchors 34 (FIG. 3E) which interconnect the semiconductor dice 36 to one another and to the substrate 10.

The thickness t of the epitaxial layer 30 and the thickness d₁ of layer 39 can be selected so that the resulting anchors 34 can be easily broken at intersecting fracture zones 31 by a preselected force, such as a vertical force, an oblique force, a shear force, a combination of these forces or a torque, for example if the semiconductor dice are peeled off. The presented force needed to break the anchors 34 can be provided when transferring the grown semiconductor dice using, for example, a stamping or wafer bonding process.

In yet another exemplary embodiment, the manufacturing method depicted in flow diagram 100, as described initially above, is performed to produce a transfer-enabled apparatus 80, as shown in FIG. 8E, having the second category non-epitaxial anchors 87 made of metallic, photoresist or other organic material. In step 102, a source substrate 10 is provided with a SiO₂ layer 91 on a silicon layer 90, as seen in FIG. 8A (which is a section taken along line BB-BB of FIG. 8C). In step 104, the substrate 10 is patterned in a single etching such that trenches 84 all have the same depth d₄ and surround substrate islands 81. The etching may go through the SiO₂ layer 91 and terminate on the Si layer as indicated in FIG. 8A or may continue into the silicon layer. In step 106, the epitaxial layer is grown, for example in this case including two layers 82 and 83, over the trenches 84 and the substrate islands 81. The epitaxial layer 82, 83 is grown to a thickness u that is less than the depth d₄ of the trenches 84. This leaves exposed parts of the side faces 86 of the substrate islands that will allow for release etching at a later step 110. After epitaxial growth, further processing can take place, such as but not limited to contact pad definition, metallization and annealing. The epitaxial layers 82, 83 on each substrate island 81 later become the semiconductor die 88, as shown in FIG. 8E.

In certain locations between the semiconductor die 88, anchors 87 are deposited in step 108. Deposition technologies can include evaporated metal deposition, droplet dispensing, inkjet deposition, screen printing, or any other suitable deposition technique. FIG. 8C shows example positions of the anchors 87 at certain locations between the semiconductor dice 88. Since the anchors only partially occupy the trenches, there is access via the trenches to the exposed side faces 86 of the substrate layer 91 (FIG. 8A) below the semiconductor die 88.

FIG. 8B (which is a section taken along line CC-CC of FIG. 8C) displaying the non-epitaxial anchors 87. The anchor 87 may be a photoresist, for example, or it may be a metallic anchor. The anchor is not necessarily deposited flush with the top surface of the semiconductor die 88, provided that the anchor 87 is in contact with both the semiconductor die 88 and the epitaxial layer 83 on the substrate 10 deposited into the trench 84 of the substrate layer 91 of the substrate 10.

In the following step 110 release etching occurs as seen in FIG. 8D causing release of the semiconductor dice 88 from the substrate 10, for example with a wet etching process. Etching occurs on the exposed side faces 86 of the substrate layer 91, removing the material of substrate layer 91 underneath the semiconductor die 88 and leaving the semiconductor die 88 suspended by the anchors 87, as seen in FIG. 8E.

FIG. 8D (which is a section taken along line BB-BB of FIG. 8C) and 8E display a typical release etching process for an oxide layer on Si. As release etching proceeds from the side faces 86 the oxide material is isotropically etched away leaving the semiconductor die secured in place by the anchors 87.

In FIG. 8E (which is a section taken along line CC-CC of FIG. 8C), the transfer-enabling apparatus 80 is shown after the release etching in step 110. The transfer-enabling apparatus 80 includes the semiconductor dice 88 suspended with an intervening gap 89 over the remainder of the layer 90 of substrate 10 by the anchors 87.

In a slight variation of the previous embodiment as seen in FIGS. 9A and 9B, the substrate 10 includes a silicon on oxide substrate (SOI) layer 90 with a buried SiO₂ layer 93 embedded in the silicon substrate layer 90. As seen in FIG. 9A (which is a section taken along line BB-BB of FIG. 9C), the substrate layer 90 is etched to a depth d₄ that is larger than the combined size of the thickness u of the epitaxial layers (here 82 and 83) and the depth of the buried oxide layer 93 in the substrate layer 90. This ensures that after growth of the epitaxial layers 82 and 83 there is still access to the buried oxide layer through the side faces 86. Subsequently deposited anchors 87 secure the semiconductor dice 88 during and after the release etching process. The release etching process removes the buried oxide layer 93 through the side faces 86 and leaves the semiconductor dice 88 suspended by the anchors 87.

The semiconductor dice 36, 88 transferred by the apparatus 4, 80 from the first or source substrate 10 to a second substrate (not shown) can be used in lighting as well as other applications.

In the description herein, embodiments disclosing specific details have been set forth in order to provide a thorough understanding of the invention, and not to provide limitation. However, it will be clear to one having skill in the art that other embodiments according to the present teachings are possible that are within the scope of the invention disclosed. All parameters, dimensions, materials, and configurations described herein are examples only and actual values of such depend on the specific embodiment.

What is claimed is:

1. A method for manufacturing a transfer-enabling apparatus, comprising:
providing a source substrate;
patterning said source substrate by forming trenches and spaced apart islands in said source substrate, one or more trenches being of width less than or equal to said islands;
growing an epitaxial layer on said source substrate so as to form semiconductor dice on said islands while leaving a portion of side faces of said islands exposed;
forming anchors attached to said source substrate and located between, connected with, and of width less than or equal to, said semiconductor dice, said anchors being formed thereby defining fracture zones; and
releasing said semiconductor dice from said source substrate so as to produce a semiconductor dice transfer-enabling apparatus wherein said semiconductor dice remain interconnected by, are suspended, and spaced above said source substrate, by said anchors until said anchors are subsequently fractured by a preselected force applied on said anchors at said fracture zones to thereby enable transfer of said semiconductor dice from said source substrate to another substrate.

2. The method of claim 1 wherein relative depths of said trenches and thicknesses of said epitaxial layer and anchors are tailored to locate said fracture zones at overlap of said anchors with said semiconductor dice.

3. The method of claim 1 wherein said anchors are formed by said growing of said epitaxial layer.

4. The method of claim 1 wherein said anchors are formed by depositing material of said anchors on said epitaxial layer at selected locations between said islands.

5. The method of claim 1 wherein said material of said anchors is one of a metallic, photoresist or organic material.

6. The method of claim 1 further comprising depositing sacrificial layers on said islands of said source substrate.

7. The method of claim 6 wherein said semiconductor dice are released from said source substrate by removing said sacrificial layers deposited on said islands of said source substrate below said semiconductor dice.

8. The method of claim 1 wherein said source substrate is made of a silicon material.

9. A method for manufacturing a transfer-enabling apparatus, comprising:
providing a source substrate;
patterning said source substrate by forming lower level trenches and spaced apart islands in said source substrate with said lower level trenches between said islands;
growing first epitaxial layers in said lower level trenches between said islands of said source substrate, said first epitaxial layers being of width less than or equal to said islands;
growing second sacrificial epitaxial layers on said islands of said source substrate so as to define upper level trenches between said islands above said first epitaxial layers;
growing a third epitaxial layer on said source substrate so as to form semiconductor dice on said second sacrificial epitaxial layers on said islands while leave portions of said second sacrificial layers exposed adjacent side faces of said islands, said growing said third epitaxial layer also forming anchors on said upper level trenches attached to said source substrate and located between, connected with, and of width less than or equal to, said semiconductor dice, said anchors defining fracture zones; and
releasing said semiconductor dice from said source substrate by removing said second sacrificial layers deposited on said islands of said source substrate below said semiconductor dice so as to produce a semiconductor dice transfer-enabling apparatus wherein said semiconductor dice remain interconnected, and are suspended and spaced above said source substrate, by said anchors until said anchors are subsequently fractured by a preselected force applied on said anchors at said fracture zones to thereby enable transfer of said semiconductor dice from said source substrate to another substrate.

10. The method of claim 9 wherein relative depths of said upper and lower level trenches and thicknesses of said third epitaxial layer and anchors are tailored to locate said fracture zones at overlap of said anchors with said semiconductor dice.

11. The method of claim 9 wherein said source substrate is made of a sapphire material.

12. A transfer-enabling apparatus, comprising:
a source substrate;
a multiplicity of semiconductor dice spaced apart from one another by trenches; and
a multiplicity of anchors each disposed between and interconnecting selected adjacent ones of said semiconductor dice and attached to said source substrate, said anchors of width less than or equal to said semiconductor dice and defining fracture zones at connections of said anchors with said semiconductor dice,
wherein said semiconductor dice are suspended, and spaced above said source substrate, by said anchors until said anchors are subsequently fractured by a preselected force applied on said anchors at said fracture zones to thereby enable transfer of said semiconductor dice from said source substrate to another substrate.

13. The apparatus of claim 12 wherein said thicknesses of said third epitaxial layer and anchors are tailored to locate said fracture zones at overlap of said anchors with said semiconductor dice.

14. The apparatus of claim 12 wherein said anchors are made of the same material as said semiconductor die.

15. The apparatus of claim 12 wherein said anchors are made of a different material from said semiconductor die.
